(19) United States
(12) Patent Application Publication
(10) Pub. No.: US 2006/0169670 A1
(43) Pub. Date: Aug. 3, 2006

(54) Method for etching a sample and etching system

(76) Inventor: Dennis Foeh, Gundelfingen (DE)

Correspondence Address: Patrick J O'Shea;O'Shea Getz & Kosakowski, Suite 912, 1500 Main Street, Springfield, MA, 01115, US

(21) Appl. No.: 10/549,081

(22) PCT Filed: Mar. 9, 2004
(86) PCT No.: PCT/EP04/02411

§ 371 Date: Oct. 31, 2005

(30) Foreign Application Priority Data
Mar. 11, 2003 (DE) 103 10 524.7

(51) Int. Cl. G01L 21/30; C23F 1/00; H01L 21/306

(52) U.S. Cl. 216/59; 216/67; 156/345.24

(57) ABSTRACT

To reduce the use of expensive reactive gas, which is frequently also environmentally harmful, during etching by a plasma the reactive gas is first fed through a reaction chamber of an etching system for stabilization, until all the process parameters are adjusted to their setpoints. During this stabilization, all of the setting parameters of the etching system are stored in a memory. After storage, the gas flow rate of an inert gas, for example helium, that is fed through the reaction chamber instead of reactive gas is raised from an initial value until the reference gas flow rate is found that causes the same setting parameters as the reactive gas. This reference gas flow rate is also stored in the memory. In each subsequent etching process, the etching system is first adjusted by the inert gas flowing through the reaction chamber with the determined reference gas flow rate, and after stabilization is complete, the reactive gas is fed through the reaction chamber and the plasma is ignited for the actual etching process.

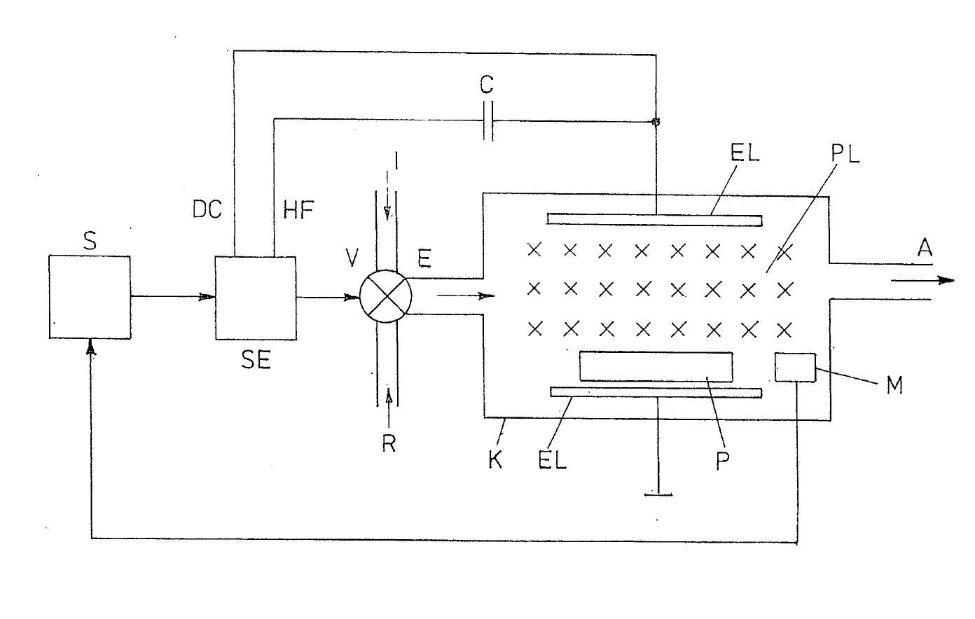

### PRIORITY INFORMATION

This patent application claims priority from PCT application PCT/EP2004/002411 filed Mar. 9, 2004, which claims the benefit of German patent application DE 103 10 524.7 filed Mar. 11, 2003.

### BACKGROUND OF THE INVENTION

The invention relates to the field of semiconductor manufacturing, and in particular to a system and method for etching of a semiconductor.

Etching methods are used, for example, in the production of semiconductor chips. A mask is placed on a layer, for example consisting of silicon, of a semiconductor. The surfaces of the layer not protected by the mask are etched by a plasma, because the plasma is able to transform the material to be etched into the gas phase.

In an etching system, the sample, for example a multilayered system of multiple layers, is located in a reaction chamber with an inlet orifice for gas infeed and with an outlet orifice for gas discharge. At the beginning of the etching process, a reactive gas mixture, for example a gas containing chlorine, with which silicon can be etched, is first fed through the reaction chamber. A control unit for the etching system adjusts all the process parameters to their setpoints. After adjustments to the setpoints, the plasma is ignited in the reaction chamber. The etching process then begins. However, multiple etching processes are to be run in a multilayered system, with different reactive gases, temperatures, pressures, and gas flow rates. The process parameters have to be reset for each sub-process. However, unutilized reactive gas is blown through the reactive chamber into the open with each reset.

It is a drawback to this method that considerable amounts of expensive and frequently also environmentally harmful reactive gases are necessary for resetting the process parameters and are then blown into the open.

Therefore, the goal of this invention is to provide a method and an etching system for etching a sample that utilizes a plasma so that as little reactive gas as possible is consumed, in order to reduce process costs and environmental pollution to the greatest possible extent.

### SUMMARY OF THE INVENTION

A method for etching a sample includes storing parameters of the etching system during stabilization with a reactive gas mixture. After storing the setting parameters, an inert gas is fed into the reaction chamber. The gas flow of inert gas is then set so that the flow of inert gas is provided that brings about the same setting parameters that the reactive gas did previously, and is likewise stored in memory, and thus replaces the actual stabilization step with reactive gas mixture. After stabilization with this inert gas, the reactive gas mixture is again fed in, without involving a change in the setting parameters, and the plasma is then ignited.

The reactive gas is fed through the reaction chamber to adjust and stabilize the setpoints. The plasma is then ignited in a second step. During stabilization, all setting parameters of the etching system are stored in memory. After storing the setting parameters, an inert gas is fed through the reaction chamber instead of the reactive gas. An inert gas is a gas that undergoes no reactions with the sample seated in the reaction chamber.

The gas flow of inert gas is modified until the flow of reference gas that brings about the same setting parameters as the reactive gas did previously, is determined. This reference gas flow rate is also stored in memory. For example, the gas flow rate of inert gas beginning with an initial value of 100 sccm is raised until the gas flow rate is determined that brings about the same setting parameters as the reactive gas did previously.

Retaining these determined setting parameters, the inert gas is then fed through the reaction chamber instead of the reactive gas, to stabilize the process. After switching to the reactive gas mixture while retaining all of the setting parameters, the plasma can be ignited immediately without any time delay.

The invention has the advantage that the setting parameters and thus the process are stabilized by an economical and environmentally harmless inert gas. For these reasons, the costs of etching are considerably reduced and environmental pollution is also considerably reduced.

Preferably, process and setting parameters for multiple different etching processes are stored in memory in an etching system according to the invention. As already mentioned, for etching processes whose parameters have already been stored, the associated parameters in memory are polled in order to set the etching system correctly.

These and other objects, features and advantages of the present invention will become more apparent in light of the following detailed description of preferred embodiments thereof, as illustrated in the accompanying drawings.

### BRIEF DESCRIPTION OF THE DRAWING

The FIGURE illustrates an etching system according to the invention.

### DETAILED DESCRIPTION OF THE INVENTION

In a reaction chamber, the sample 100 to be etched is positioned between two electrodes 102, 104. A first output on a line 108 of a control unit provides a high d.c. voltage to the first electrode 102, while the other electrode 104 is grounded. A second output of the control unit 106 on a line 110 provides a high-frequency high voltage signal that through a capacitor 112 to the first electrode 102. A control output on a line 114 from the control unit 106 is connected to a control valve 116 to which the inert gas 118 and the reactive gas 120 are connected. Either the inert gas 118 or the reactive gas mixture 120 is fed from the control valve 116 through an inlet orifice 122 into a reaction chamber 124, which has an outlet orifice 126 for gas discharge. A measuring sensor 128, for example, is located in the reaction chamber 124 to detect the process parameters. The measuring sensor 128 provides a sensed signal on a line 130 to a memory 132 to store the process and setting parameters.

At the beginning of an etching process, the control unit 106 sets the control valve 116 so that the reactive gas mixture 120 flows through the reaction chamber 124. In a first stabilization step, all of the process parameters that the measuring sensor 128 measures are adjusted to their setpoints. In the second stabilization step, the plasma is ignited. All of the setting parameters of the etching system are then stored in the memory 132 while the process is running.

After all of the parameters have been stored, the control unit 106 sets the control valve 116 so that the inert gas 118 then flows through the reaction chamber 124 instead of the reactive gas 120. The control unit 106 then raises the gas flow of inert gas, beginning with an initial value, until the reference gas flow is reached that causes the same setting parameters as the reactive gas did previously. This reference gas flow is likewise stored in the memory 132.

To etch the sample, the reactive gas, instead of the inert gas, is fed through the reaction chamber at the reference gas flow rate determined by the inert gas, while retaining the determined setting parameters. The plasma is then ignited to etch the sample.

In each further etching process of the same kind, the gas flow rate of the reactive gas is adjusted to the value associated by the inert gas. For example, parameters for multiple different etching processes, reactive gases, and samples can be stored in the memory 132. The measuring and storage processes are necessary only for novel etching processes. Parameters stored in the memory 132 can be accessed for etching processes already carried out. For these reasons, the etching process and the etching system according to the invention are distinguished by low process costs and low environmental pollution. The more stabilization steps that are necessary, the greater are the effects of these advantages of the invention.

Although the present invention has been illustrated and described with respect to several preferred embodiments thereof, various changes, omissions and additions to the form and detail thereof, may be made therein, without departing from the spirit and scope of the invention.

What is claimed is:

1. Method for etching a sample in an etching system utilizing a plasma of a reactive gas mixture that is fed through a reaction chamber with an inlet orifice and with an outlet orifices, in which the sample to be etched is located, with a device for igniting and maintaining the plasma, comprising:
inputting a reactive gas mixture to the reaction chamber; with a control unit for the etching system adjusting all the process parameters to their setpoints, and with the plasma being ignited in a second step,
setting parameters of the etching system at least are stored in a memory (S), during the first process step,
inputting an inert gas to the reaction chamber after the storage of the setting parameters,
modifying the gas flow rate of the inert gas, the gas flow rate is determined that causes the same setting parameters as the reactive gas mixture did previously;.
inert gas is fed into the reaction chamber (K) at the determined reference gas flow rate of inert gas until the setting parameters in the process are stabilized, the inert gas is then switched over to reactive gas mixture while retaining the setting parameters,
the plasma is then ignited.

2. The method according to claim 1, where the gas flow rates for a plurality of different reactive gases are determined and are stored in memory.

3. The method of claim 2, where at the beginning of an etching process, the inert gas is fed through the reaction chamber with the reference gas flow rate stored for the intended reactive gas until stabilization occurs, the reactive gas is then fed through the reaction chamber while retaining the setting parameters, and the plasma is ignited for etching.

4. The method of claim 1 where helium, argon, or xenon is provided as the inert gas.

5. Method according to one of claims 1 to 4, characterized in that the determined value for the reference gas flow rate is stored in memory (S).

6. Etching system for etching a sample (P), comprising: utilizing a reactive gas that can be fed through a reaction chamber with an inlet orifice for the infeed of gas and with an outlet orifice for the discharge of gas, in which the sample to be etched is located, with a device for generating an electrical high voltage field to ignite and maintain the plasma, wherein the reactive gas can be fed through the reaction chamber in a first stabilization step, with a control unit for the etching system being provided to adjust all the process parameters to their setpoints, and with the plasma being ignitable in a second step,
characterized in that
all of the setting parameters of the etching system can be stored in a memory while the process is running,
an inert gas can be fed through the reaction chamber instead of the reactive gas after the storage of the setting parameters,
by modifying the gas flow rate of inert gas, the reference gas flow rate that causes the same setting parameters as the reactive gas mixture did previously can be determined and likewise stored in the memory,
to etch the sample, the reactive gas can be fed through the reaction chamber instead of the inert gas, while retaining the determined setting parameters,
and the plasma can be ignited without stabilization with reactive gas and without a time delay.

7. The etching system of claim 6, where at the beginning of an etching process, the inert gas can be fed through the reaction chamber with the reference gas flow rate belonging to the intended reactive gas and stored, until stabilization occurs, and then the intended reactive gas can be fed through the reaction chamber while maintaining the setting parameters, and the plasma can be ignited to etch the sample.

8. The etching system of claim 6, where helium is provided as the inert gas.

9. The etching system of claims 6, where the ignition device comprises electrodes or an electrodes/coils arrangement.
